(19) United States
(12) Patent Application Publication
(10) Pub. No.: US 2009/0085168 A1
(43) Pub. Date: Apr. 2, 2009

(54) Semiconductor device and method for manufacturing same

(75) Inventors: Nobuji Kobayashi, Kakamigahara-shi (JP); Isamu Tomizawa, Gifu-shi (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., Moriguchi-shi (JP); SANYO SEMICONDUCTOR CO., LTD., Ora-gun (JP)

(21) Appl. No.: 12/232,488

(22) Filed: Sep. 18, 2008

(30) Foreign Application Priority Data
Sep. 27, 2007 (JP) 2007-250762

(51) Int. Cl. H01L 23/00

(52) U.S. Cl. 257/620; 257/E23.194

(57) ABSTRACT

When a photoresist or the like is spin-coated on a semiconductor chip comprising a seal ring is formed, striation due to corners of the seal ring is suppressed. A wiring metal layer and a contact are layered, and a seal structure (28) that surrounds an element forming region (22) on a semiconductor chip (20) is formed. A planar shape of the seal ring structure (28) has shape that is, at a basic level, a rectangle corresponding with the shape of the semiconductor chip (20), but with cutoffs present on corner parts (60) of the rectangle. Specifically, the seal ring structure (28) is disposed along a periphery of a rectangle having corner cutoffs.

### CROSS-REFERENCE TO RELATED APPLICATION

The priority application number JP2007-250762 upon which this patent application is based is hereby incorporated by reference.

### BACKGROUND OF THE INVENTION

1. Field of the Invention

The present invention relates to a semiconductor device and a method for manufacturing same. The invention relates more particularly to a semiconductor device equipped with a seal ring that prevents the ingress of moisture, dampness, or the like from a cutting surface of a semiconductor chip that has been separated from a semiconductor wafer by dicing; and to a method for manufacturing same.

2. Description of the Related Art

A plurality of semiconductor integrated circuits (ICs) are formed on a wafer; and, in a dicing step, the wafer is cut into semiconductor chips on which each of the ICs is formed. An interlayer insulating film is exposed on the side surface of the diced semiconductor chips; and moisture, dampness, or the like penetrate therethrough, which can cause the IC to malfunction or fail. A seal ring is accordingly formed to prevent the ingress of moisture, dampness, and the like from the side surface of the semiconductor chip. FIG. 4 is a plan view of a semiconductor chip 2. As shown in FIG. 4, a seal ring 6 is formed on the chip 2 in the periphery of a region 4 in which the IC is formed.

The seal ring 6 is formed using a metal layer for forming a wiring on the semiconductor substrate. Each metal wiring film made from aluminum (Al) or another material and used to form multilayer wiring is patterned, and a metal layer pattern having a shape that corresponds to the seal ring 6 is formed. An opening is provided in the interlayer insulating films respectively layered between the plurality of metal layer patterns and between the bottommost metal layer pattern and the semiconductor substrate. A tungsten plug or the like is embedded in the aperture. The seal ring 6 is thereby formed so as to be connected in a vertical direction from the uppermost layer of the plurality of layers of metal layer patterns to the surface of the substrate.

In consideration of issues such as gaplessly laying out the semiconductor chips on the wafer, obtaining a reliable per-wafer chip yield, and the ease with which dicing is performed, the planar shape of the semiconductor chip is generally made rectangular; and, accordingly, the IC-forming region 4 and the seal ring 6 are also essentially made rectangular.

A photoresist or another liquid material may be spin-coated on the seal ring 6 either after the seal ring has been completely formed or while it is in the process of being formed. In such cases, a problem has been the prevalence of striation, via which edges are formed in the corners of the rectangular seal ring 6.

Striation of the liquid material coated on the wafer can be minimized by increasing the thickness of the coated film. However, the film thickness accordingly required of the liquid material increases in accordance with the step of the seal ring 6. Therefore, in a case where thicker wiring metal layers are used, e.g., to form a wiring through which a large current will pass, the requisite film thickness of the liquid material reaches a level at which coating becomes very difficult to perform, and striation becomes difficult to suppress. A drawback has also been presented in the case of a photoresist or other films that are patterned after coating, wherein the difficulty with which the film is etched increases as the film thickness increases.
Patent Document 1: Japanese Laid-open Patent Application No. 6-97374
Patent document 2: Japanese Laid-open Patent Application No. 2000-232104

### SUMMARY OF THE INVENTION

The present invention was contrived in order to resolve the above problems, and it is an object thereof to provide a semiconductor device structure for reducing striation of a liquid material spread over the surface formed a seal ring, which occurs in a manufacturing step; and a manufacturing method whereby such striation is minimized.

The semiconductor device according to the present invention comprises an element-forming region disposed on a semiconductor substrate; and a seal ring structure surrounding the element forming region and composed of a metal material layered on the semiconductor substrate. The seal ring structure is disposed along a periphery of a planar surface shape having a corner cutoff.

### BRIEF DESCRIPTION OF THE DRAWINGS

FIG. 1 is a schematic plan view of a semiconductor chip that is an embodiment of the present invention;

FIG. 2 is a schematic vertical cross-sectional view along straight line A-A′ of the semiconductor chip shown in FIG. 1;

FIG. 3A is a diagram schematically showing a flow of liquid material in a corner part of a seal ring structure having a planar shape that is rectangular and does not have corner cutoffs;

FIG. 3B is a diagram schematically showing a flow of liquid material in a corner part of the seal ring structure having a planar shape that is rectangular and has corner cutoffs; and

FIG. 4 is a plan view of a conventional semiconductor chip.

### DESCRIPTION OF THE PREFERRED EMBODIMENTS

Hereinafter, embodiments of the present invention (“embodiments”) will be described based on the drawings.

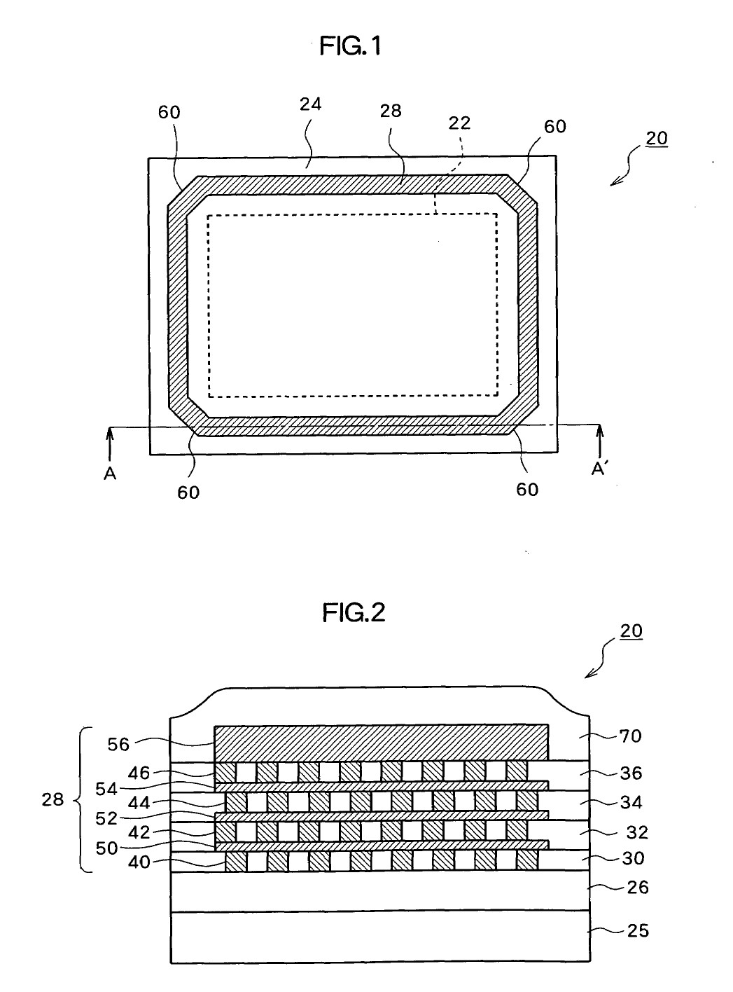

FIG. 1 is a schematic plan view of a semiconductor chip 20, which is a semiconductor device of an embodiment; and FIG. 2 is a schematic vertical cross-sectional view of the semiconductor chip 20 along straight line A-A′ in FIG. 1.

Transistors and other circuit elements and wiring are formed within an element forming region 22 provided in a central part of the semiconductor chip 20. They are formed in a step wherein the semiconductor chip 20 is in a wafer state; i.e., has not been cut from the wafer. In a region 24, which is on the outer side of the element forming region 22, a thick LOCOS (local oxide film) 26, for example, is formed on a surface of the wafer (semiconductor substrate 25). The region 24 thereby isolates the element forming region 22 from an edge of the semiconductor chip 20. A seal ring structure 28 is formed in this isolating region 24, surrounding the element forming region 22. A structure composed of a wiring and the seal ring structure 28 is formed on the semiconductor substrate 25 by layering, patterning, and otherwise processing materials in the wafer state. The materials used at this time to form a photoresist, an interlayer insulating film, an upper flattening film, and a protection film are in liquid state; and are applied on the substrate surface. The coating step is generally performed using spin-coating. When the step of forming the IC in the wafer state is complete, dicing is performed to cut the semiconductor chip 20 from the wafer in a rectangular shape.

Hereinafter, the structure of the seal ring structure 28 and the forming step will be described. The seal ring structure 28 is a structure in which metal plugs 40, 42, 44, 46, which are formed in interlayer insulating films 30, 32, 34, 36, are layered in an alternating manner with seal rings (single-layer seal rings) 50, 52, 54, 56, which are composed of a metal layer for forming a wiring.

Specifically, the interlayer insulating film 30 is layered on the LOCOS 26, and a plurality of contact holes formed using a photolithographic technique are arranged in the interlayer insulating film 30 along the position where the seal ring structure 28 is formed. These contact holes are filled with tungsten (W), and tungsten plugs are formed as metal plugs 40.

The surface of the interlayer insulating film 30 and metal plugs 40 is flattened using CMP (chemical mechanical polishing), and a first Al film, which is a wiring metal layer, is deposited on that surface. The first Al film is patterned, and the first layer seal ring 50 is formed simultaneously with the wiring of element forming region 22.

The interlayer insulating film 32 is layered on the patterned first Al film; and the same step used for forming the contacts and wiring in the element forming region 22 is used to layer the second layer metal plug 42 and seal ring 52 in the stated order on top of the first layer seal ring 50, in the same manner as with the first layer. The first layer seal ring 50 and second layer seal ring 52 are connected by the metal plug 42.

Then, similarly, the interlayer insulating film 34 is layered on the second Al film; and the same step used for forming the contacts and wiring in the element forming region 22 is used to layer the third layer metal plug 44 and seal ring 54 in the stated order on top of the second layer seal ring 52. The second layer seal ring 52 and third seal ring 54 are connected by the metal plug 44.

Last, the metal plug 46 and seal ring 56 of the fourth and uppermost layer of the seal ring structure 28 are laid. This step is also performed in the same manner as those performed for the first to third layers. The metal plug 46 is embedded in the interlayer insulating film 36 that has been laid on the third Al film, and the fourth layer Al film is deposited thereupon. The fourth Al film is patterned using a photolithographic technique, and the fourth layer seal ring 56 is laid at the same time that the wiring is formed in the element forming region 22. The third layer seal ring 54 and fourth layer seal ring 56 are connected by the metal plug 46.

A complementary MOSFET (CMOS) or other element having a relatively low drive current is combined with a double-diffused MOSFET (DMOS) or other element having a relatively high drive current in the semiconductor chip 20. The fourth Al film is made thicker because of this structure, and is used to form wiring that can accommodate high current in correspondence with the DMOS or the like. For example, the fourth Al film is formed to a thickness of about 3 μm. The first through third Al films are used to form wiring that can accommodate a relatively low allowable current in correspondence with the CMOS or the like, and are formed to a thickness of about 0.6 μm.

The fourth layer seal ring 56 thus forms a large step that is about 3 μm above the surface of the interlayer insulating film 36, which serves as the base of the fourth layer seal ring 56. Accordingly, when another layer is to be disposed thereupon, step coverage and the like must be taken into greater consideration than when another layer is disposed on each of the seal rings 50, 52, 54 of the bottom first to third layers formed from thin Al film. In particular, when a liquid material such as a photoresist is applied using spin-coating and a layer for covering the step of the fourth layer seal ring 56 is formed, striation readily occurs in the corner part, as mentioned previously. The striation can be minimized in the semiconductor chip 20 by giving the seal ring structure 28 a planar shape that is, at a basic level, a rectangle that corresponds to the shape of semiconductor chip 20, but with corner cutoffs made in a corner part 60 of the rectangle. More specifically, the seal ring structure 28 is disposed along a periphery of the rectangle with corner cutoffs.

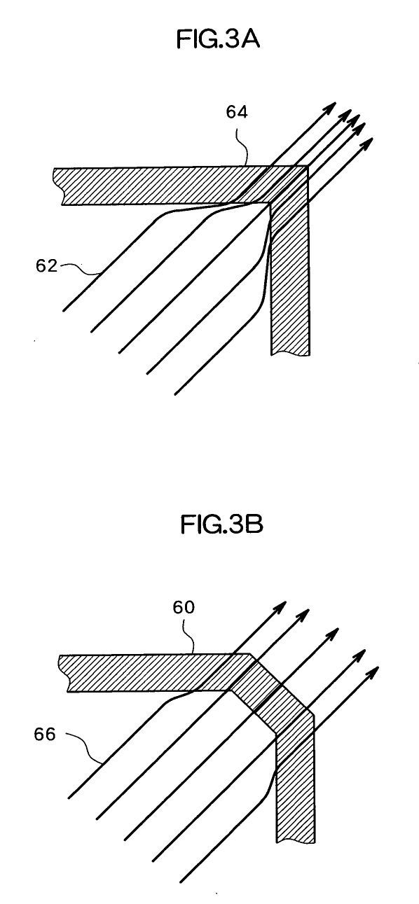

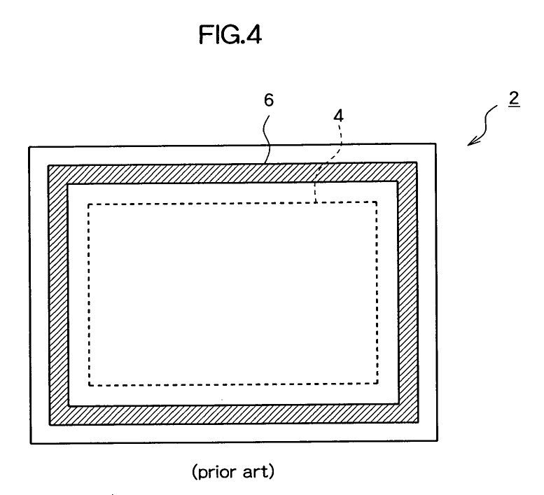

The cutoff of the corner part 60 can be formed such that the corners of the rectangle are cut diagonally (at a slant of about 45 degree with respect to their adjacent sides), as shown in FIG. 1. FIG. 3A and FIG. 3B are diagrams schematically showing a flow of liquid material in a corner part. FIG. 3A shows a case where the planar shape of the seal ring structure is that of a rectangle that does not have corner cutoffs; and FIG. 3B shows a case where the planar shape of the seal ring structure is that of a rectangle that has corner cutoffs. As shown in FIG. 3A, in a conventional corner part 64, wherein the steps of the seal ring structure are connected at right angles, the flow of the liquid material from within the seal ring structure to the corner part 64 (arrows 62) readily concentrates in the corner thereof. As a result, it is thought that the difference in the density of the liquid material readily increases in the direction perpendicular to that of the flow on the outer side of the seal ring structure. In contrast, the flow of the liquid material (arrow 66) in the notched rectangular corner part 60 shown in FIG. 3B is less concentrated, and the difference in density can be reduced. The difference between whether or not the corners are notched can thus be conceptually grasped with respect to the application of the liquid material. This difference is presumably related to whether it is possible to minimize striation that forms an edge in a notched corner part, as with the corner part 60 of the semiconductor chip 20.

It shall be apparent that the corner cutoff does not have to be rectilinear, as shown in FIG. 1; a curve such as a circular arc is also suitable. The scale of the corner cutoff; e.g., the length of the notched part inside the seal ring structure 28, can be determined after considering the height of the step, the viscosity of the liquid material, or other parameters. For example, qualitatively, the notch is preferably larger if the step is larger. However, the larger the notch becomes, the more the element forming region 22 will serve as a restriction, and the more dead space will be formed in the corner of the semiconductor chip 20. Therefore, various conditions should be taken into account when deciding what the notching degree should be.

An example shall now be given of a step for coating a liquid material on the fourth layer seal ring 56. For example, in a case where the semiconductor chip 20 is a device in which a light-receiving part is present in the element forming region 22, a structure may be obtained wherein the interlayer insulating films 30, 32, 34, 36 are etched from the region corresponding to the light-receiving part, an opening is provided in this region, and the attenuation of incident light in the interlayer insulating films is prevented. In this case, the photoresist is spin-coated on the fourth layer seal ring 56, and the photoresist is used to form a mask for etching the interlayer insulating film 30 and the like.

Additionally, for example, a silicone nitride film is deposited as a protective film on the wafer on which the fourth layer seal ring 56 is formed, and polyimide is spin-coated as a protective film 70 for the silicone nitride film.

In the present embodiment, attention has been focused on the fourth layer seal ring 56, but seal rings 50, 52, 54 of the first to the third layer can be notched in the same manner as the seal ring 56, whereby the entirety of the seal ring structure 28 can be given a planar surface shape having corner cutoffs.

According to the present invention, for example, the degree to which the liquid material gets concentrated in the corner part after flowing from the interior of the seal ring structure to the corner part of the seal ring structure can be made lower than when the corners are not notched. As a result, there will be less of a change in the density of the liquid material along a direction running perpendicular to the flow, and striation will be minimized.

What is claimed is:

1. A semiconductor device comprising an element-forming region disposed on a semiconductor substrate; and a seal ring structure surrounding the element forming region, the seal ring being composed of a metal material layered on the semiconductor substrate; wherein
the seal ring structure is disposed along a periphery of a planar surface shape having a corner cutoff.

2. A semiconductor device comprising an element-forming region disposed on a semiconductor substrate; and a seal ring structure surrounding the element forming region, the seal ring being composed of a metal material layered on the semiconductor substrate, wherein
a coating layer that is caused to flow in liquid state and is applied in a layered form is present on a surface of the semiconductor device on which a step is created by the seal ring structure; and
the seal ring structure is disposed along a periphery of a planar surface shape having a corner cutoff.

3. The semiconductor device according to claim 1, wherein
the planar surface on which the seal ring structure is disposed is rectangular in overall appearance; and has a corner-cutoff region obtained by linearly cutting an apex of a corner of the rectangle at an angle of approximately 45°.

4. The semiconductor device according to claim 1, wherein the planar surface on which the seal ring structure is disposed
is rectangular in overall appearance; and has a corner-cutoff region obtained by cutting an apex of a corner of the rectangle into an arcuate shape.

5. The semiconductor device according to claim 1, wherein
the semiconductor device has a multilayer wiring structure formed using a plurality of layers of a metal film for forming a wiring; and
the metal material of the seal ring structure is formed using each of the wiring metal films.

6. The semiconductor device according to claim 5, wherein
the semiconductor device has a combination of a first semiconductor element and a second semiconductor element that requires a drive current that is larger than that of the first semiconductor element; the semiconductor device having a wiring composed of a first wiring metal film that has a thickness corresponding to the drive current of the first semiconductor element, and a wiring composed of a second wiring metal film that has a greater thickness than the first wiring metal layer film in response to the drive current of the second semiconductor element.

7. The semiconductor device according to claim 6, wherein
the second wiring metal film is disposed on the uppermost layer of the plurality of layers of the wiring metal film.
